(19) United States
(12) Patent Application Publication
(10) Pub. No.: US 2026/0214804 A1
(43) Pub. Date: Jul. 23, 2026

(54) MOUNTING STRUCTURE OF MULTILAYER ELECTRONIC COMPONENT

(71) Applicant: SAMSUNG ELECTRO-MECHANICS CO., LTD., Suwon-si (KR)

(72) Inventors: Won Chul SIM, Suwon-si (KR); Se Hun PARK, Suwon-si (KR); Soo Hwan SON, Suwon-si (KR); Young Ghyu AHN, Suwon-si (KR)

(73) Assignee: SAMSUNG ELECTRO-MECHANICS CO., LTD., Suwon-si (KR)

(21) Appl. No.: 19/397,454

(22) Filed: Nov. 21, 2025

(30) Foreign Application Priority Data
Jan. 20, 2025 (KR) 10-2025-0007977

(51) Int. Cl. H05K 1/18; H01G 4/30

(52) U.S. Cl. CPC H05K 1/181; H01G 4/30; H05K 2201/10015; H05K 2201/10977

(57) ABSTRACT

A mounting structure of a multilayer electronic component according to an example embodiment of the present disclosure includes: a printed circuit board including an electrode pad; a multilayer electronic component disposed on the printed circuit board, the multilayer electronic component including a body and external electrodes disposed on the body; a coating layer disposed to cover at least a portion of the multilayer electronic component; and a molding layer disposed on the coating layer, and a Young's modulus of the coating layer is less than 500 MPa.

### CROSS-REFERENCE TO RELATED APPLICATION(S)

This application claims benefit of priority to Korean Patent Application No. 10-2025-0007977 filed on Jan. 20, 2025, in the Korean Intellectual Property Office, the disclosure of which is incorporated herein by reference in its entirety.

### TECHNICAL FIELD

The present disclosure relates to a mounting structure of a multilayer electronic component.

Multilayer ceramic capacitors (MLCC), a type of multilayer electronic component, are chip-shaped capacitors mounted on the printed circuit boards in various electronic devices, including Liquid Crystal Display (LCD) and Plasma Display Panels (PDP), computers, smartphones, and mobile phones, serving to charge or discharge electricity therein or therefrom. The MLCCs are used in a variety of electronic devices due to their compact size, high capacitance, and ease of mounting.

Because the dielectric layer of an MLCC is piezoelectric, the dielectric layer vibrates when DC or AC voltage is applied thereto. This vibration is transmitted to the printed circuit board through a solder, thus generating a vibrational sound. This vibrational sound may be at an audible frequency that is unpleasant to humans, and this unpleasant vibrational sound is known as acoustic noise. Furthermore, regardless of user awareness, when piezoelectric vibrations of the MLCC occur in the high-frequency range above 20 kHz, this may cause malfunctions in various sensors used in the IT and automotive industries.

Specifically, forming a molding layer over MLCCs to protect the MLCCs on printed circuit boards may have the unintended effect of increasing acoustic noise, and thus, research is required on an MLCC mounting structure that may suppress noise generation.

### SUMMARY

An aspect of the present disclosure is to provide a mounting structure of a multilayer electronic component that may reduce acoustic noise.

However, the aspects of the present disclosure are not limited to the above-described contents, and may be more easily understood in the process of describing specific embodiments of the present disclosure.

A mounting structure of a multilayer electronic component according to an example embodiment of the present disclosure may include: a printed circuit board including an electrode pad; a multilayer electronic component disposed on the printed circuit board, the multilayer electronic component including a body and external electrodes disposed on the body; a coating layer disposed to cover at least a portion of the multilayer electronic component; and a molding layer disposed on the coating layer, and a Young's modulus of the coating layer is less than 500 MPa.

One effect of the present disclosure is to provide a mounting structure of a multilayer electronic component that may reduce acoustic noise.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a perspective view schematically illustrating a multilayer electronic component according to an example embodiment of the present disclosure;

FIG. 2 is a cross-sectional view schematically illustrating a cross-section taken along line I-I′ of FIG. 1;

FIG. 3 is a cross-sectional view schematically illustrating a cross-section taken along line II-II′ of FIG. 1;

FIG. 4 is a plan view schematically illustrating a mounting structure of a multilayer electronic component according to an example embodiment of the present disclosure;

FIG. 5 is a plan view schematically illustrating a mounting structure of a multilayer electronic component according to another embodiment of the present disclosure; and

FIG. 6 is a graph evaluating acoustic noise of Inventive Example and Comparative Example.

### DETAILED DESCRIPTION

Hereinafter, example embodiments of the present disclosure will be described with reference to specific example embodiments and the attached drawings. The example embodiments of the present disclosure may, however, be exemplified in many different forms and should not be construed as being limited to the specific embodiments set forth herein. Furthermore, the example embodiments disclosed herein are provided for those skilled in the art to better explain the present disclosure. Accordingly, in the drawings, the shapes and dimensions of elements may be exaggerated for clarity, and the same reference numerals will be used throughout to designate the same or like elements.

Furthermore, in order to clearly describe the present disclosure in the drawings, contents unrelated to the description are omitted, and since sizes and thicknesses of each component illustrated in the drawings are arbitrarily illustrated for convenience of description, the present disclosure is not limited thereto. Furthermore, components with the same function within the same range of ideas are described using the same reference numerals. Throughout the specification, when a certain portion “includes” or “comprises” a certain component, this indicates that other components are not excluded and may be further included unless otherwise noted.

In the drawing, an X-direction may be defined as a thickness (T) direction, a Y-direction may be defined as a length (L) direction, and a Z-direction may be defined as a width (W) direction.

### Multilayer Electronic Component

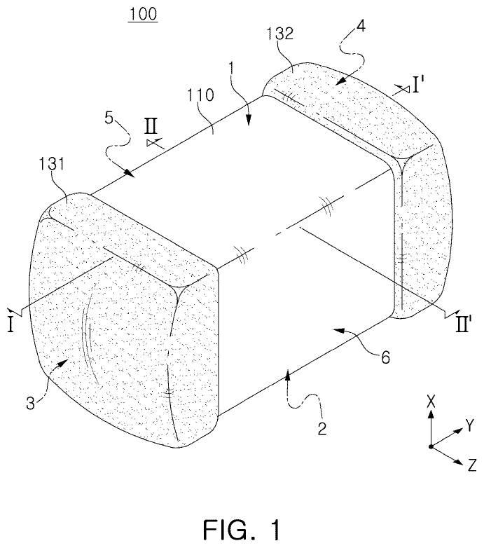

FIG. 1 is a perspective view schematically illustrating a multilayer electronic component according to an example embodiment of the present disclosure.

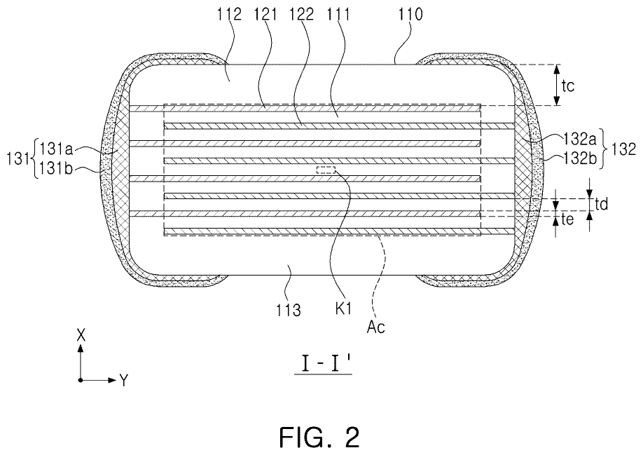

FIG. 2 is a cross-sectional view schematically illustrating a cross-section taken along line I-I′ of FIG. 1.

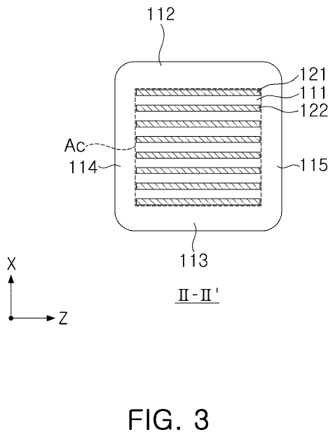

FIG. 3 is a cross-sectional view schematically illustrating a cross-section taken along line II-II′ of FIG. 1.

Hereinafter, a multilayer electronic component 100 according to an example embodiment of the present disclosure will be described in detail with reference to FIGS. 1 to 3. While a multilayer ceramic capacitor will be described as an example of a multilayer electronic component, the present disclosure is not limited thereto and may be applied to various multilayer electronic components, such as inductors, piezoelectric elements, varistors, or thermistors.

The multilayer electronic component 100 may include a body 110 and external electrodes 131 and 132 disposed on the body 110.

Although there are no particular limitations on the specific shape of the body 110, as illustrated, the body 110 may be formed in a hexahedral or similar shape. Due to shrinkage of ceramic powder particles included in the body 110 during a sintering process, or a polishing process on corners of the body 110, the body 110 may not be a perfectly straight hexahedral shape, but may have a substantially hexahedral shape.

The body 110 may have first and second surfaces 1 and 2 opposing each other in the thickness direction, third and fourth surfaces 3 and 4 connected to the first and second surfaces 1 and 2 and opposing each other in the length direction, and fifth and sixth surfaces 5 and 6 connected to the first to fourth surfaces 1, 2, 3 and 4 and opposing each other in the width direction.

The body 110 may include a dielectric layer 111 and internal electrodes 121 and 122 alternately disposed with the dielectric layers 111. A plurality of dielectric layers 111 forming the body 110 are in a sintered state, and boundaries between adjacent dielectric layers 111 may be so integrated so as to be difficult to identify without using a scanning electron microscope (SEM).

The dielectric layer 111 may include, for example, a perovskite compound represented by ABO₃ as a main component. The perovskite compound represented by ABO₃ may include, for example, one or more of BaTiO₃, (Ba₁₋ₓCaₓ)TiO₃ (0<x<1), Ba(Ti_{1-y}Ca_{y})O₃ (0<y<1), (Ba₁₋ₓCaₓ)(Ti_{1-y}Zr_{y}) O₃ (0<x<1, 0<y<1), Ba(Ti_{1-y}Zr_{y}) O₃ (0<y<1), CaZrO₃ (Ca₁₋ₓSrₓ)(Zr_{1-y}Ti_{y}) O₃ (0<x≤0.5, 0<y≤0.5).

An average thickness td of the dielectric layer 111 is not particularly limited. The average thickness td of the dielectric layer 111 may be, for example, 0.1 μm to 20 μm, 0.1 μm to 10 μm, 0.1 μm to 5 μm, 0.1 μm to 2 μm, or 0.1 μm to 0.4 μm.

The body 110 may include a capacitance formation portion Ac forming a capacitance, by including a first internal electrode 121 and second internal electrodes 121 and 122 disposed within the body 110 and alternately disposed with the dielectric layer 111 interposed therebetween. A stacking direction of the internal electrodes 121 and 122 may be in a thickness direction or a width direction.

The first internal electrode 121 may be spaced apart from the fourth surface 4 and connected to a first external electrode 131 on the third surface 3. The second internal electrode 122 may be spaced apart from the third surface 3 and connected to a second external electrode 132 on the fourth surface 4.

The conductive metal included in the internal electrodes 121 and 122 may be one or more of Ni, Cu, Pd, Ag, Au, Pt, Sn, W, Ti and alloys thereof, and the conductive metal may include, more preferably Ni, but the present disclosure is not limited thereto.

An average thickness te of the internal electrodes 121 and 122 is not particularly limited. The average thickness te of the internal electrodes 121 and 122 may be, for example, 0.1 μm to 3.0 μm, 0.1 μm to 1.0 μm, or 0.1 μm to 0.4 μm.

The average thickness td of the dielectric layer 111 and the average thickness te of the internal electrodes 121 and 122 may be measured by scanning cross-sections of the body 110 in a thickness direction and a longitudinal direction (L-T) using a scanning electron microscope (SEM) at 10,000× magnification. More specifically, the average thickness td of the dielectric layer 111 may be measured by measuring thicknesses at multiple points on the dielectric layer 111, for example, five points equally spaced apart from each other in a longitudinal direction, and then taking an average value thereof. Furthermore, the average thickness te of the internal electrodes 121 and 122 may be measured by measuring thicknesses at multiple points on the internal electrode 121 and 122, for example, five points equally spaced apart from each other in the longitudinal direction, and then taking an average value thereof. The five points equally spaced apart from each other may be designated in the capacitance formation portion Ac. Meanwhile, when these average values are measured for performing measurement on each of the 10 dielectric layers 111 and 10 internal electrodes 121 and 122, the average thickness td of the dielectric layer 111 and the average thickness te of the internal electrodes 121 and 122 may be further generalized.

The body 110 may include cover portions 112 and 113 disposed on opposite surfaces of the capacitive formation portion Ac in the thickness direction, and margin portions 114 and 115 disposed on opposite surfaces of the capacitive formation portion Ac in the width direction. The cover portions 112 and 113 and the margin portions 114 and 115 may have a similar configuration to the dielectric layer 111, except that the cover portions 112 and 113 and the margin portions 114 and 115 do not include internal electrodes.

An average thickness tc of the cover portions 112 and 113 is not particularly limited. The average thickness tc of the cover portions 112 and 113 may be, for example, 150 μm or less, 100 μm or less, 30 μm or less, or 20 μm or less. The average thickness tc of the cover portions 112 and 113 may be, for example, 5 μm or more, 10 μm or more, or 30 μm or more. Here, the average thickness tc of the cover portions 112 and 113 refers to an average thickness of each of the first cover portion 112 and the second cover portion 113.

The average thickness tc of the cover portions 112 and 113 may be an average value obtained by measuring the thickness at five points equally spaced apart from each other on the L-T cross-section of the multilayer electronic component 100.

External electrodes 131 and 132 may be disposed on the third and fourth surfaces 3 and 4 of the body 110. The external electrode 131 may include a first external electrode 131 disposed on the third surface 3 and extending on portions of the first, second, fifth and sixth surfaces 1, 2, 5 and 6, and a second external electrode 132 disposed on the fourth surface 4 and extending on portions of the first, second, fifth, and sixth surfaces 1, 2, 5 and 6.

The type or shape of the external electrodes 131 and 132 is not particularly limited, and may have a multilayer structure. For example, the external electrodes 131 and 132 may include base electrode layers 131a and 132a in contact with the internal electrodes 121 and 122 and plating layers 131b and 132b disposed on the base electrode layers 131a and 132a.

The base electrode layers 131a and 132a may include a sintered electrode layer including a metal and glass. The metal included in the sintered electrode layer may include, for example, Cu, Ni, Pd, Pt, Au, Ag, Pb and/or alloys including the same. The glass included in the sintered electrode layer may include, for example, one or more oxides of Ba, Ca, Zn, Al, B and Si.

Meanwhile, the base electrode layers 131a and 132a may be comprised solely of a sintered electrode layer, but the present disclosure is not limited thereto, and the base electrode layers 131a and 132a may include a sintered electrode layer including metal and glass, and a resin electrode layer disposed on the sintered electrode layer and including metal particles and resin.

The metal particles included in the resin electrode layer may include at least one of spherical particles and flake-shaped particles. The metal particles included in the resin electrode layer may include, for example, Cu, Ni, Pd, Pt, Au, Ag, Pb, Sn, and/or alloys including the same. The resin included in the resin electrode layer may include, for example, one or more of an epoxy resin, an acrylic resin and ethyl cellulose.

The plating layers 131b and 132b may include, for example, Ni, Sn, Pd, and/or alloys including the same, and may be formed of a plurality of layers. The plating layers 131b and 132b may be, for example, Ni plating layers or Sn plating layers, and may be in a form in which the Ni plating layer and the Sn plating layer are sequentially formed, and the plating layers 131b and 132b may also include a plurality of Ni plating layers and/or a plurality of Sn plating layers.

While the drawing illustrates a structure in which the multilayer electronic component 100 has two external electrodes 131 and 132, the present disclosure is not limited thereto, and the number and shape of the external electrodes 131 and 132 may vary depending on the shape of the internal electrodes 121 and 122 or other purposes.

A length of the multilayer electronic component 100 may be greater than a width and a thickness thereof, respectively, but the present disclosure is not limited thereto. For example, the length of the multilayer electronic component 100 may be less than the width thereof. The width of the multilayer electronic component 100 may be less than or greater than the thickness thereof, which may vary depending on the specifications or characteristics of the multilayer electronic component 100.

### Manufacturing Method of Multilayer Electronic Component

Hereinafter, an example of a method of forming the multilayer electronic component 100 will be described. However, the manufacturing method of the multilayer electronic component 100 is not limited thereto.

First, ceramic powder particles for forming the dielectric layer 111 is prepared. The ceramic powder particles may include, for example, one or more of BaTiO₃, (Ba₁₋ₓCaₓ)TiO₃ (0<x<1), Ba(Ti_{1-y}Ca_{y})O₃ (0<y<1), (Ba₁₋ₓCaₓ)(Ti_{1-y}Zr_{y}) O₃ (0<x<1, 0<y<1), Ba(Ti_{1-y}Zr_{y}) O₃ (0<y<1), CaZrO₃, (Ca₁₋ₓSrₓ)(Zr_{1-y}Ti_{y})O₃ (0<x≤0.5, 0<y≤0.5). The BaTiO₃ powder particles may be synthesized, for example, by reacting a titanium raw material such as titanium dioxide with a barium raw material such as barium carbonate. Methods for synthesizing the ceramic powder particles include, for example, a solid-state method, a sol-gel method, a hydrothermal synthesis method, and the like, but the present disclosure is not limited thereto. Next, the prepared ceramic powder particles are dried and ground, and then mixed with an organic solvent such as ethanol and a binder such as polyvinyl butyral to manufacture a ceramic slurry, and the ceramic slurry is applied to a carrier film and dried to manufacture a ceramic green sheet.

Next, an internal electrode conductive paste including metal powder particles, a binder and an organic solvent, is printed onto the ceramic green sheet to a predetermined thickness using a screen-printing or gravure printing method, thus forming an internal electrode pattern.

Then, the ceramic green sheet on which the internal electrode pattern is printed is peeled from the carrier film, and then a predetermined number of ceramic green sheets on which the internal electrode pattern is printed are stacked and pressed, thus forming a ceramic stack body. A predetermined number of ceramic green sheets in which the internal electrode pattern is not formed may be stacked on upper and lower portions of the ceramic stack body in order to form cover portions 112 and 113 after firing. The ceramic stack body is then cut to have a predetermined chip size, and the cut chips are sintered to form the body 110. The firing may be performed, for example, in a 1.0% H₂/99.0% N₂ to 3.5% H₂/96.5% N₂ (H₂O/H₂/N₂ atmosphere) at a temperature of 1000° C. to 1400° C. for 1 to 3 hours.

Next, external electrodes 131 and 132 are formed. For example, when the base electrode layers 131a and 132a include a fired (sintered) electrode layer, the body 110 may be dipped in a conductive paste for external electrodes, including metal powder, glass frit, a binder and an organic solvent, and then the conductive paste for external electrodes may be sintered at a temperature of 500° C. to 900° C. to form the sintered electrode layer.

For example, when the base electrode layers 131a and 132a include a resin electrode layer, the body may be dipped in a conductive resin composition including metal powder particles, a resin, a binder, and an organic solvent, followed by a curing heat treatment at a temperature of 250° C. to 550° C. to form the resin electrode layer.

Additionally, electrolytic plating and/or electroless plating may be additionally performed to form plating layers 131b and 132b on the base electrode layers 131a and 132a.

### Mounting Structure of Multilayer Electronic Component

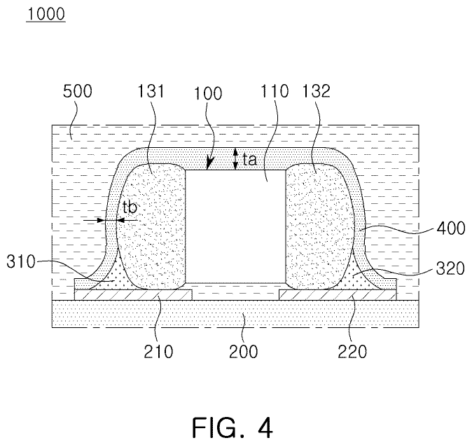

FIG. 4 is a plan view schematically illustrating the mounting structure of a multilayer electronic component according to an example embodiment of the present disclosure.

Referring to FIG. 4, a mounting structure 1000 of a multilayer electronic component may include a printed circuit board 200, a multilayer electronic component 100 disposed on the printed circuit board 200, a coating layer 400, and a molding layer 500.

The printed circuit board 200 may include, for example, a resin such as glass epoxy or a ceramic such as glass ceramic. The printed circuit board 200 may have, for example, a form in which a plurality of insulating layers are stacked. The printed circuit board 200 may include electrode pads 210 and 220. A first electrode pad 210 connected to the first external electrode 131 and a second electrode pad 220 connected to the second external electrode 132 may be disposed on an upper surface (e.g., first surface) of the printed circuit board 200. The electrode pads 210 and 220 may include, for example, one or more of Cu, Ni, Au, Ag, Pd, Pt, and alloys thereof.

The multilayer electronic component 100 may be mounted on the electrode pads 210 and 220 via solders 310 and 320. The solders 310 and 320 may be disposed to contact the electrode pads 210 and 220 and the external electrodes 131 and 132, respectively. The solders 310 and 320 may include a first solder 310 connecting the first electrode pad 210 and the first external electrode 131, and a second solder 320 connecting the second electrode pad 220 and the second external electrode 132. A lower surface (e.g., a second surface) of the body 110, adjacent to the upper surface of the printed circuit board 200, may be defined as a mounting surface. The mounting surface may be any one of the first, second, fifth or sixth surfaces 1, 2, 5 or 6. The present disclosure will hereinafter be described based on an example embodiment in which the mounting surface is the first or second surface 1 and 2, but the present disclosure is not limited thereto. When the mounting surface is the first or second surface 1 and 2, the internal electrodes 121 and 122 may be disposed parallel to the upper surface of the printed circuit board 200.

The mounting structure 1000 of the multilayer electronic component may include a coating layer 400 disposed to cover at least a portion of the multilayer electronic component 100 and a molding layer 500 disposed on the coating layer 400.

Conventionally, a molding layer disposed to cover the multilayer electronic component mounted on a printed circuit board (PCB) to protect the multilayer electronic component from external impacts was formed on printed circuit board. In this case, the molding layer firmly fixes an upper region of the multilayer electronic component, and thus suppresses deformation of the upper region of the multilayer electronic component. However, a side effect thereof is that deformation of the lower region of the multilayer electronic component adjacent to the PCB increases, resulting in increased acoustic noise of the component.

Conversely, the mounting structure 1000 for the multilayer electronic component may interpose the coating layer 400 between the multilayer electronic component 100 and the molding layer 500, thereby suppressing a phenomenon of the molding layer 500 firmly fixing the upper region of the multilayer electronic component 100. This suppresses deformation of the lower region of the multilayer electronic component 100 due to piezoelectric vibrations, and consequently reduces acoustic noise of the multilayer electronic component 100.

According to an example embodiment of the present disclosure, a Young's modulus of the coating layer 400 may be less than 500 MPa. When the Young's modulus of the coating layer 400 is less than 500 MPa, the acoustic noise of the multilayer electronic component 100 may be more effectively reduced. A lower limit of the Young's modulus of the coating layer 400 is not particularly limited, but may be 10 MPa or greater, taking into account the high-temperature reliability, and adhesive strength of the coating layer 400.

The Young's modulus (E) of the coating layer 400 may be determined by fabricating a specimen of the coating layer 400 in a rod shape, for example, a dog-bone shape, and measuring the stress (o) and displacement (s) while pulling the specimen using a tensile tester, and then calculating a ratio of stress to displacement (o/s). Other methods and/or tools appreciated by one of ordinary skill in the art, even if not described in the present disclosure, may also be used.

In an example embodiment, the Young's modulus of the coating layer 400 may be lower than the Young's modulus of the molding layer 500. As the coating layer 400 having a lower Young's modulus than the molding layer 500 covers the upper region of the multilayer electronic component 100, the acoustic noise of the multilayer electronic component 100 may be more effectively reduced. A ratio of the Young's modulus of the coating layer 400 to the Young's modulus of the molding layer 500 may be, for example, 0.0005 or more and 0.025 or less. The Young's modulus of the molding layer 500 may be measured using the same method as that used to measure the Young's modulus of the coating layer 400. Other methods and/or tools appreciated by one of ordinary skill in the art, even if not described in the present disclosure, may also be used.

The coating layer 400 may be disposed to cover at least a portion of the multilayer electronic component 100, for example, the coating layer 400 may be disposed to cover a portion of the body 110 and a portion of the external electrodes 131 and 132. For example, the coating layer 400 may be disposed on an upper surface (e.g., first surface) of the body 110 and extend onto a side surface of the body 110. Here, the side surface of the body 110 may refer to the third and fourth surfaces 3 and 4. The coating layer 400 may be disposed to cover at least a portion of the solder 310 and 320 and at least a portion of the electrode pads 210 and 220. For example, the coating layer 400 may be disposed to cover a portion of upper surfaces (e.g., first surfaces) of the electrode pads 210 and 220.

The molding layer 500 may be disposed on the coating layer 400 to cover at least a portion of the coating layer 400 and at least a portion of the printed circuit board 200. The molding layer 500 may be disposed to cover, for example, four side surfaces connecting the upper and lower surfaces (e.g., first and second surfaces) of the electrode pads 210 and 220. In an example embodiment, the molding layer 500 may be disposed to extend between the lower surface (e.g., second surface) of the body 110 and the upper surface of the printed circuit board 200. That is, the molding layer 500 may be disposed to fill a space between the lower surface of the body 110 and the upper surface of the printed circuit board 200. Thus, the molding layer 500 may be disposed to cover portions of the first, second, fifth and sixth surfaces 1, 2, 5 and 6 of the body 110, respectively.

Meanwhile, a thickness of the coating layer 400 is not particularly limited. However, as the thickness of the coating layer 400 increases, the stiffness of the coating layer 400 tends to increase. As the stiffness of the coating layer 400 increases, the upper region of the multilayer electronic component 100 may be more firmly fixed by the coating layer 400. Accordingly, as deformation of the upper region of the multilayer electronic component 100 is suppressed, deformation of the lower region of the multilayer electronic component 100 increases, which may increase acoustic noise of the multilayer electronic component 100. Accordingly, in an example embodiment, a thickness ta of the coating layer 400 measured on the upper surface of the body 110 may be 45 μm or less. When ta is 45 μm or less, acoustic noise may be more effectively reduced. A lower limit of the ta is not particularly limited, but in consideration of the high-temperature reliability and adhesive strength of the coating layer 400, the ta may be 4 μm or more.

In an example embodiment, the thickness ta of the coating layer 400 measured on the upper surface of the body 110 may be greater than the thickness of the coating layer 400 measured on the side surface of the body 110.

Meanwhile, the ta and tb may be measured from an image obtained by observing a longitudinal-thickness direction (L-T) cross-section of the mounting structure 1000 of the multilayer electronic component passing through a widthwise central portion of the multilayer electronic component 100, using a microscope, such as a scanning electron microscope. Other methods and/or tools appreciated by one of ordinary skill in the art, even if not described in the present disclosure, may also be used. The ta may refer to the thickness of the coating layer 400 measured on a longitudinal central portion of the multilayer electronic component 100 in the L-T cross-section. The tb may refer to the thickness of the coating layer 400 measured in the center of the thickness direction of the multilayer electronic component 100 in the L-T cross-section.

A material included in the coating layer 400 is not particularly limited and may be appropriately selected considering the Young's modulus of the coating layer 400, and the like. For example, the coating layer 400 may include a silicone resin. The silicone resin may include, for example, epoxy silicone and/or polyimide silicone.

The method of forming the coating layer 400 is not particularly limited, but the coating layer 400 may be formed by coating a resin composition including a silicone resin onto the multilayer electronic component 100 using a vapor deposition method such as CVD or sputtering, or a liquid coating method, and then curing the resin composition at a temperature of 100° C. to 300° C. for several minutes to several tens of minutes. The Young's modulus of the coating layer 400 may be controlled, for example, by adjusting the type of silicone resin or curing conditions. Furthermore, the Young's modulus of the coating layer 400 may be adjusted by adding additives, such as plasticizers or inorganic fillers, to the resin composition used to form the coating layer 400.

The molding layer 500 may include an epoxy molding compound (EMC). The molding layer 500 may be formed using a known method. For example, the molding layer 500 may be formed by disposing a printed circuit board 200 having a multilayer electronic component 100 installed therein in a mold for molding, injecting liquefied EMC at a high temperature into the mold, and then curing the liquefied EMC.

Meanwhile, as illustrated in FIG. 4, the coating layer 400 may be disposed to cover a single multilayer electronic component 100, but the present disclosure is not limited thereto.

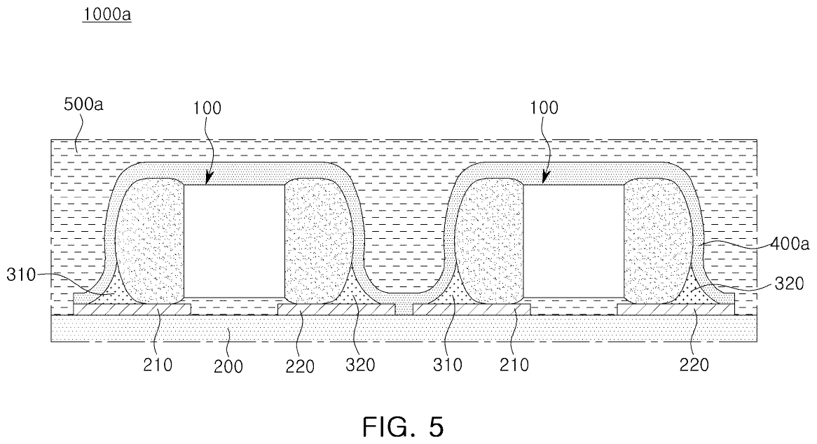

FIG. 5 is a plan view schematically illustrating the mounting structure of a multilayer electronic component according to another example embodiment of the present disclosure. Hereinafter, a mounting structure 1000a of the multilayer electronic component according to an example embodiment of the present disclosure will be described with reference to FIG. 5, but components identical to or similar to the components of the multilayer electronic component mounting structure 1000 described in FIG. 4 will be designated by the same or similar reference numerals, and redundant descriptions will be omitted.

Referring to FIG. 5, the multilayer electronic component mounting structure 1000a may include a coating layer 400a and a molding layer 500a disposed on the coating layer 400a, and the coating layer 400a may be disposed to cover two or more multilayer electronic components 100. For example, the coating layer 400a may be disposed to cover several to several dozen multilayer electronic components 100.

The coating layer 400a may be continuously disposed on two or more multilayer electronic components 100. The molding layer 500a may be disposed to extend into a space between adjacent multilayer electronic components, among the plurality of multilayer electronic components 100.

### Inventive Example 1

A 1005-size (length: approximately 1.0 mm, width: approximately 0.5 mm, and thickness: approximately 0.5 mm) multilayer ceramic capacitor was mounted on an electrode pad of a printed circuit board using solder. A resin composition containing silicone resin was then applied to the multilayer ceramic capacitor and cured to form a coating layer, and a molding layer including EMC was then formed on the printed circuit board on which the coating layer is formed, using a molding die, thereby preparing a sample substrate of an inventive example.

The sample substrate of a comparative example was manufactured using the same method as the sample substrate of the example, except that a coating layer was not formed on the multilayer ceramic capacitor and only the molding layer was formed thereon.

Then, acoustic noise of the inventive example and comparative examples was measured. After mounting the sample substrates of Inventive Example and Comparative Example on a measurement jig, AC voltage was applied to the multilayer ceramic capacitors mounted on the jig using a DC power supply and a function generator. The acoustic noise was then measured in an anechoic chamber using a microphone installed directly above the sample substrates of the Inventive Example and Comparative Example.

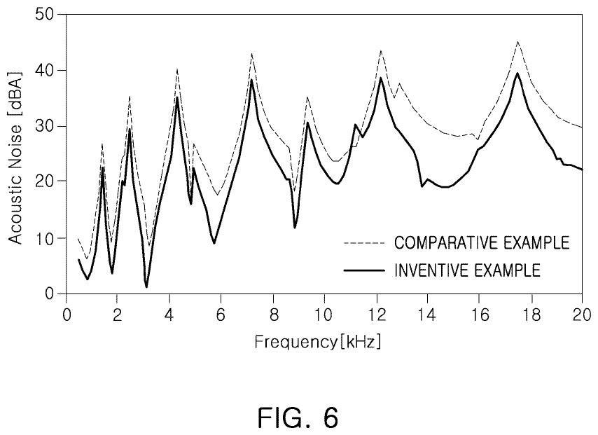

FIG. 6 is a graph evaluating the acoustic noise of Comparative Example and Comparative Example. Referring to FIG. 6, it may be confirmed that the Acoustic Noise of the Inventive Example is reduced as compared to the Comparative Example. This is likely because the coating layer prevents the upper region of the multilayer ceramic capacitor from being rigidly fixed by the molding layer, thereby suppressing increased deformation of the lower region of the multilayer ceramic capacitor.

### Inventive Example 2

After preparing a sample substrate having the same type as Inventive Example 1, changes in acoustic noise according to the Young's modulus of the coating layer were measured and is listed in Table 1 below. The Young's modulus of the coating layer was measured by manufacturing dog-bone-shaped specimens of the coating layer of each sample substrate for each sample number, and measuring the stress (o) and displacement (s) while pulling the sample using a tensile tester. Acoustic noise was measured using the same method as Experimental Example 1.

Meanwhile, the Comparative Example (REF) was fabricated using the same method as the previously described sample substrate, except that the coating layer was not formed on the multilayer ceramic capacitor. A reduction ratio (AA/N) of the acoustic noise of Sample Nos. 1 to 7 as compared to the acoustic noise of the Comparative Example was calculated and is listed in Table 1 below.

TABLE 1

| Sample | Young's | Acoustic | ΔA/N |
|---|---|---|---|
| Number | modulus (MPa) | Noise(dBA) | [%] |
| REF | — | 55.0 | — |
| 1 | 10 | 49.8 | 9.5 |
| 2 | 20 | 49.9 | 9.3 |
| 3 | 50 | 50.2 | 8.8 |
| 4 | 100 | 50.6 | 8.0 |
| 5 | 200 | 51.2 | 7.0 |
| 6 | 500 | 52.2 | 5.0 |
| 7 | 1000 | 52.9 | 3.9 |

Referring to Table 1, Sample Nos. 6 and 7 exhibited a reduction in acoustic noise of less than 5%, as the Young's modulus of the coating layer was greater than 500 MPa. This phenomenon is expected to be due to the excessive increase in the Young's modulus of the coating layer and strong fixing of the upper region of the multilayer ceramic capacitor.

Conversely, Sample Nos. 1 to 5 exhibited a reduction in acoustic noise of more than 7%, as compared to the comparative example in which only the molding layer was formed. Accordingly, it is confirmed that Sample Nos. 1 to 5 in which a Young's modulus of the coating layer is less than 500 MPa effectively reduced the acoustic noise of the multilayer ceramic capacitor.

### Experimental Example 3

After preparing a sample substrate having the same shape as Inventive Example 1, changes in acoustic noise according to the thickness of the coating layer were measured, and the results are shown in Table 2. The coating layer thickness ta measured on the upper surface of the body was measured from a microscopic image of the L-T cross-section of the sample substrate passing through a widthwise central portion of the multilayer ceramic capacitor. The ta was measured in the longitudinal center of the multilayer ceramic capacitor.

Meanwhile, the comparative example (REF) was manufactured using the same method as the sample substrate described above, except that no coating layer was formed on the multilayer ceramic capacitor. The acoustic noise was measured using the same method as Inventive Example 1. A reduction rates (LA/N) of acoustic noise of Sample Nos. 8 to 14 as compared to the acoustic noise of the comparative example were calculated and are limited in Table 2 below.

TABLE 2

| Sample | | Acoustic | ΔA/N |
|---|---|---|---|
| Number | ta(μm) | Noise(dBA) | [%] |
| REF | — | 55.0 | — |
| 8 | 4 | 48.5 | 11.8 |
| 9 | 6 | 49.8 | 9.5 |
| 10 | 14 | 50.2 | 8.7 |
| 11 | 35 | 50.9 | 7.5 |
| 12 | 45 | 52.3 | 5.0 |
| 13 | 52 | 53.9 | 2.0 |
| 14 | 65 | 55.0 | 0 |

Referring to Table 2 above, it is confirmed that in Sample No. 13 and 14, as ta exceeds 45 μm, acoustic noise reduction rates are less than 2%. Accordingly, it is determined that as ta exceeds 45 μm, the rigidity of the coating layer increases excessively, leading to increased acoustic noise in the multilayer ceramic capacitor.

Conversely, in Sample No. 8 to 12, acoustic noise reduction rates were more than 5% as compared to the comparative example in which only the molding layer was formed. Accordingly, it is confirmed that Sample No. 8 to 12 in which ta is less than 45 μm effectively reduce acoustic noise in the multilayer ceramic capacitor.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

In addition, the expression ‘an example embodiment’ used in the present disclosure does not denote the same example embodiment, and is provided to emphasize and explain different unique characteristics. However, the example embodiments presented above do not preclude being implemented in combination with the features of another embodiment. For example, although items described in a specific embodiment are not described in another embodiment, the items may be understood as a description related to another embodiment unless a description opposite or contradictory to the items is in another embodiment.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

What is claimed is:

1. A mounting structure of a multilayer electronic component, comprising:
a printed circuit board including an electrode pad;
a multilayer electronic component disposed on the printed circuit board, the multilayer electronic component including a body and external electrodes disposed on the body;
a coating layer disposed to cover at least a portion of the multilayer electronic component; and
a molding layer disposed on the coating layer,
wherein a Young's modulus of the coating layer is less than 500 MPa.

2. The mounting structure of a multilayer electronic component according to claim 1, wherein the Young's modulus of the coating layer is lower than a Young's modulus of the molding layer.

3. The mounting structure of a multilayer electronic component according to claim 2, wherein a ratio of the Young's modulus of the coating layer to the Young's modulus of the molding layer is 0.0005 or more and 0.025 or less.

4. The mounting structure of a multilayer electronic component according to claim 1, further comprising a solder disposed to be in contact with each of the electrode pad and the external electrodes.

5. The mounting structure of a multilayer electronic component according to claim 4, wherein the coating layer is disposed to cover at least a portion of the solder and at least a portion of the electrode pad.

6. The mounting structure of a multilayer electronic component according to claim 1, wherein the coating layer is disposed to cover a portion of a first surface of the electrode pad,
the molding layer is disposed to cover four side surfaces of the electrode pad, and
the four side surfaces connect the first surface and a second surface of the electrode pad.

7. The mounting structure of a multilayer electronic component according to claim 1, wherein the molding layer is disposed to extend between a second surface of the body and a first surface of the printed circuit board.

8. The mounting structure of a multilayer electronic component according to claim 1, wherein the coating layer is disposed on a first surface of the body and extends on a side surface of the body, and
a thickness of the coating layer, as measured on the first surface of the body, is 45 μm or less.

9. The mounting structure of a multilayer electronic component according to claim 1, wherein the coating layer is disposed on a first surface of the body and disposed to extend on a side surface of the body, and
a thickness of the coating layer, as measured on the first surface of the body, is greater than a thickness of the coating layer, as measured on the side surface of the body.

10. The mounting structure of a multilayer electronic component according to claim 1, wherein the coating layer includes a silicone resin, and
the molding layer includes an epoxy molding compound (EMC).

11. The mounting structure of a multilayer electronic component according to claim 1, wherein the coating layer is disposed to cover one multilayer electronic component.

12. The mounting structure of a multilayer electronic component according to claim 1, wherein the multilayer electronic component includes a plurality of multilayer electronic components disposed on the printed circuit board, and
the coating layer is disposed to cover two or more multilayer electronic components among the plurality of multilayer electronic components.

13. The mounting structure of a multilayer electronic component according to claim 1, wherein a Young's modulus of the coating layer is 10 MPa or more and less than 500 MPa.

14. The mounting structure of a multilayer electronic component according to claim 8, wherein a thickness of the coating layer, as measured on the first surface of the body, is 4 μm or more.

15. The mounting structure of a multilayer electronic component according to claim 1, wherein the body includes a dielectric layers and internal electrodes alternately arranged with the dielectric layers.

16. The mounting structure of a multilayer electronic component according to claim 10, wherein the silicone resin include epoxy silicone, polyimide silicone, or both.
